(19) United States
(12) Patent Application Publication
(10) Pub. No.: US 2024/0012028 A1
(43) Pub. Date: Jan. 11, 2024

(54) LARGE PROBE CARD FOR TESTING ELECTRONIC DEVICES AND RELATED MANUFACTURING METHOD

(71) Applicant: TECHNOPROBE S.P.A., Cernusco Lombardone (LC) (IT)

(72) Inventor: Flavio MAGGIONI, Cernusco Lombardone (LC) (IT)

(73) Assignee: TECHNOPROBE S.P.A., Cernusco Lombardone (LC) (IT)

(21) Appl. No.: 18/253,444

(22) PCT Filed: Nov. 26, 2021
(86) PCT No.: PCT/EP2021/083115

§ 371 Date: May 18, 2023

(30) Foreign Application Priority Data
Nov. 27, 2020 (IT) 102020000028838

(51) Int. Cl. G01R 1/073; G01R 3/00

(52) U.S. Cl. CPC G01R 1/07314; G01R 3/00; G01R 1/07357

(57) ABSTRACT

A method of manufacturing a probe card for functionality testing of devices under test (DUT) is disclosed having the steps of providing an interface board configured for interfacing the probe card to a testing apparatus, providing a stiffener, connecting an interposer in the shape of a monobloc of material to the stiffener, cutting the monobloc according to a predetermined pattern after connecting it to the stiffener, thereby defining a plurality of modules which are independent and separated from each other, associating the interface board with the stiffener, and associating a probe head with the interposer. The probe head includes a plurality of contact elements adapted to electrically connect the interposer to contact pads of the devices under test. A probe card obtained by the method is also disclosed.

### FIELD OF APPLICATION

The present disclosure relates to a probe card, and to a related manufacturing method, for testing electronic devices integrated on a semiconductor wafer, in particular a large probe card for testing memory devices (such as for instance DRAMs), and the following description is made with reference to this application field with the only purpose of simplifying the exposition thereof.

### PRIOR ART

As it is well known, a probe card is essentially an electronic device adapted to electrically connect a plurality of contact pads of a microstructure, in particular an electronic device integrated on a semiconductor wafer, with corresponding channels of a testing apparatus that performs the functionality testing thereof.

This test is useful for detecting and isolating defective circuits as early as in the production phase. Normally, the probe cards are therefore used for the test of the circuits integrated on wafers before cutting and assembling them inside a containment package.

Generally, a probe card comprises a probe head, in turn comprising a plurality of contact probes held by at least one guide or by at least one pair of guides (or supports) which are substantially plate-shaped and parallel to each other. Said guides are equipped with suitable guide holes and are arranged at a certain distance from each other in order to leave a free space or air gap for the movement and possible deformation of the contact probes, which are slidingly housed in said guide holes. The pair of guides in particular comprises an upper guide and a lower guide, both provided with respective guide holes within which the contact probes axially slide, said probes being usually made of special alloys with good electric and mechanical properties.

The good connection between the contact probes and the contact pads of the device under test is ensured by the pressure of the probe head on the device itself, wherein, during said pressing contact, the contact probes undergo a bending inside the air gap between the two guides and a sliding inside the relative guide holes. Probe heads of this type are commonly referred to as “vertical probe heads”.

Substantially, the vertical probe heads have an air gap where a bending of the contact probes occurs, wherein said bending may be facilitated through a suitable configuration of the probes themselves or of the guides thereof.

By way of example, FIG. 1 schematically shows a probe card of the known type, globally indicated with reference number 15 and including a probe head 1 comprising in turn at least one upper plate-shaped support or guide 2, usually indicated as “upper die”, and a lower plate-shaped support or guide 3, usually indicated as “lower die”, having respective guide holes 4 and 5 within which a plurality of contact probes 6 slide.

Each contact probe 6 has at an end a contact tip 7 apt to abut onto a contact pad 8 of a device under test that is integrated on a wafer 9, thus performing the mechanical and electric contact between said device under test and a testing apparatus (not represented) which said probe card 15 is an end element of.

As indicated in FIG. 1, the upper guide 2 and the lower guide 3 are suitably spaced apart by an air gap 10 which allows the contact probes 6 to deform.

The probe head 1 is a vertical probe head in which, as previously seen, the good connection between the contact probes 6 and the contact pads 8 of the device under test is ensured by the pressure of the probe head on the device itself, wherein the contact probes 6, which are movable within the guide holes 4 and 5 formed in the guides 2 and 3, undergo a bending inside the air gap 10 and a sliding inside said guide holes during said pressing contact.

In some cases, the contact probes are fixedly fastened to the probe head itself at the upper plate-shaped support: such probe heads are referred to as “blocked probe heads”.

However, more frequently, probe heads with non-blocked probes (i.e. not fixedly fastened) are used, the probes being held interfaced to a so-called board, possibly through a microcontact board: such probe heads are referred to as “unblocked probe heads”. The microcontact board is usually called “space transformer” since, besides contacting the probes, it also allows spatially redistributing the contact pads made thereon with respect to the contact pads on the device under test, in particular relaxing the distance constraints between the centers (pitches) of the pads themselves.

In this case, still with reference to FIG. 1, each contact probe 6 has a further end area or region ending with a so-called contact head 11 towards a contact pad 12 of a plurality of contact pads of a space transformer 13 of the probe card 15 which comprises the probe head 1. The good electric connection between contact probes 6 and space transformer 13 is ensured by means of the pressing contact of the contact heads 11 of the contact probes 6 onto the contact pads 12 of said space transformer 13 analogously to the contact between the contact tips 7 and the contact pads 8 of the device under test integrated on the wafer 9.

Furthermore, the probe card 15 comprises a support plate 14, generally a printed circuit board (PCB), connected to the space transformer 13, through which the probe card 15 interfaces with the testing apparatus (not shown).

The proper operation of a probe card is basically linked to two parameters: the vertical movement, or overtravel, of the contact probes, and the horizontal movement, or scrub, of the contact tips of said contact probes onto the contact pads.

All these features should be evaluated and calibrated in the manufacturing step of the probe card, since the proper electric connection between the contact probes and the device under test should always be ensured.

Furthermore, according to the known solutions, the support plate 14 is kept in position through a stiffener 16.

Generally, the space transformer 13 has very reduced thicknesses and thus it has significant problems of planarity (flatness). For this reason, it is also generally associated with a stiffener (not shown in FIG. 1), which is configured to make the whole assembly more rigid and resistant and allows reducing planarity defects, which often affect the proper operation of the probe cards made according to the aforementioned technology.

Generally, the testing methodologies require the probe card to be able to withstand extreme temperatures, as well as to work correctly at different temperatures (both very high and very low temperatures). However, in this case, the thermal expansions of the components of the probe card may affect its correct behavior. In fact, the components of the probe cards of the known type (such as the stiffener, the PCB, and the interposer) are usually fastened by screws and have different thermal expansion coefficients, as well as they are subjected to different temperatures. During the test (for example at high or low temperature), due to the different thermal expansion coefficients of the materials which said components are made of and due to the constraints there between, the components themselves tend to arch, causing malfunctions of the probe card as a whole, even causing an absence of contact with the contact pads of the device under test.

This problem is particularly important in case of large probe cards, such as for instance the probe cards for testing memory devices such as DRAMs. For this kind of probe cards, in fact, failure to control the thermal expansion of the components entails considerable problems in the testing phase.

The technical problem of the present invention is to provide a probe card for testing electronic devices having functional and structural features such as to overcome the limitations and drawbacks still affecting the known solutions, in particular a large probe card which allows ensuring the correct execution of the tests even at extreme temperatures and to withstand considerable temperature variations, being at the same time easy to assemble.

### SUMMARY OF THE INVENTION

The solution idea underlying the present invention is to provide a probe card through a methodology whereby the interposer is initially fastened to a stiffener in the shape of a monobloc of material and subsequently cut into a plurality of modules which are independent and separate from each other. In this way, the interposer is initially associated with the probe card as a single block of material, without the need to align the single modules, which then allow an improved control of the thermal expansion of the probe card during the test.

Based on this solution idea, the above technical problem is solved by a method for manufacturing a probe card for the functionality testing of devices under test, comprising the steps of providing an interface board configured to interface the probe card to a testing apparatus, providing a stiffener, connecting an interposer to the stiffener, said interposer being in the shape of at least one monobloc of material, cutting the at least one monobloc of the interposer according to a predetermined pattern after connecting it to the stiffener, thereby defining a plurality of modules which are independent and separated from each other, starting from said at least one monobloc, associating the interface board to the stiffener, and associating a probe head with the interposer, said probe head comprising a plurality of contact elements adapted to electrically connect the interposer with contact pads of the devices under test.

More particularly, the invention comprises the following additional and optional features, taken singularly or in combination if needed.

According to an aspect of the present invention, the stiffener may comprise a first stiffener portion and a second stiffener portion, the method comprising the step of arranging the interface board between the first stiffener portion and the second stiffener portion, wherein the interposer is connected to the second stiffener portion, in particular to a lower face thereof.

According to an aspect of the present invention, the cutting of the interposer may be performed by laser cutting or water cutting or a combination thereof.

According to an aspect of the present invention, the monobloc of material of the interposer may be made of a multilayer organic material.

According to an aspect of the present invention, the interposer may be fastened to the stiffener through screws or through glue, preferably through screws.

According to an aspect of the present invention, the method may comprise the step of associating the interface board to the stiffener by means of connecting elements with clearance, said connecting elements with clearance being floatingly housed in a plurality of respective seats made in said interface board, so as to make a floating association of said interface board with said stiffener.

According to an aspect of the present invention, the method may comprise the preliminary step of defining in the second stiffener portion a plurality of housing seats, said housing seats being in a number identical to that of the modules of the plurality of modules of the interposer, which are arranged at respective housing seats.

According to an aspect of the present invention, the method may comprise the preliminary step of shaping the monobloc of material of the interposer, thereby forming a plurality of projections therein, said projections being housed into corresponding housing seats of the second stiffener portion before cutting said monobloc of material.

According to an aspect of the present invention, the method may comprise the step of inserting a plurality of electrical connection elements into the housing seats, said electrical connection elements being configured to electrically connect each module of the plurality of modules of the interposer with the interface board.

According to an aspect of the present invention, the method may comprise the step of selecting the stiffener material among Invar, Kovar, Alloy 42 or FeNi alloys, Titanium or alloys thereof, Aluminum or alloys thereof, Steel, Brass, Macor.

According to an aspect of the present invention, the probe head may be manufactured through at least the following steps:
providing a housing or containment element for at least partially housing the contact elements;
arranging a lower guide at a lower face of the containment element, said lower face, during the test, facing towards the devices under test;
arranging an upper guide at an upper face of the containment element, said upper face being opposite the lower face, wherein the containment element is interposed between the lower guide and the upper guide, and wherein said guides are in the shape of at least one single plate connected to the containment element, the method further comprising the step of cutting at least one of the lower guide or the upper guide thereby defining a plurality of guide portions that are independent and separated from each other.

According to an aspect of the present invention, the method may comprise the preliminary step of gluing the lower guide and the upper guide to the containment element, the method further comprising the step of forming in the guides respective guide holes for housing the contact elements, said step being performed prior to said gluing and cutting step. Alternatively, the guide holes may be formed after the gluing and cutting step.

The present invention also relates to a probe card for the functionality testing of devices under test, comprising a stiffener, an interface board associated with the stiffener and configured to interface the probe card to a testing apparatus, and an interposer connected to the stiffener, said interposer comprising a plurality of modules independent and separated from each other, wherein the modules of the interposer are obtained by cutting at least one monobloc of material initially connected to the stiffener, said probe card further comprising a probe head comprising a plurality of contact elements adapted to electrically connect the interposer with contact pads of the devices under test.

According to an aspect of the present invention, the stiffener may comprise a first stiffener portion and a second stiffener portion, the interface board being arranged between the first stiffener portion and the second stiffener portion, the interposer being connected to the second stiffener portion.

According to an aspect of the present invention, the interposer may be made of a multilayer organic material.

According to an aspect of the present invention, the contact elements may comprise a body which extends along a longitudinal axis between a first end and a second and opposite end, said first end being adapted to contact the contact pads of the devices under test, said second end being adapted to contact the interposer in a non-fixed manner, i.e., they are not rigidly and fixedly fastened (constrained) thereto but they abut thereonto.

According to an aspect of the present invention, the interface board may be a printed circuit board.

According to an aspect of the present invention, the interposer may comprise a number of modules ranging from 50 to 150.

According to an aspect of the present invention, the stiffener may be made of at least one of Invar, Kovar, Alloy 42 or FeNi alloys, Titanium or alloys thereof, Aluminum or alloys thereof, Steel, Brass, Macor.

According to an aspect of the present invention, the probe card may comprise connecting elements with clearance which are adapted connect the interface board to the stiffener, said connecting elements with clearance being floatingly housed in a plurality of respective seats formed in said interface board, said connecting elements with clearance being configured to floatingly associate the interface board with the stiffener.

According to an aspect of the present invention, the second stiffener portion may comprise a plurality of housing seats, and at each of said housing seats there is a corresponding module of the plurality of modules of the interposer.

According to an aspect of the present invention, the probe card may comprise a plurality of electrical connection elements which are housed in the housing seats and are configured to electrically connect the interposer and the interface board to each other.

According to an aspect of the present invention, each module may comprise a projection inserted in a respective housing seat of the plurality of housing seats of the second stiffener portion.

According to an aspect of the present invention, each module of the plurality of modules may be fastened (constrained) to the second stiffener portion by means of at least two screws.

According to an aspect of the present invention, the probe head may comprise a housing or containment element configured to house at least partially the contact elements, a lower guide arranged at a lower face of the containment element, said lower face, during the test, facing towards the devices under test, and an upper guide arranged at an upper face of the containment element, said upper face being opposite the lower face, wherein said containment element is interposed between the lower guide and the upper guide, and wherein at least one of the guides is divided into a plurality of guide portions which are independent and separated from each other, said guide portions being obtained by cutting at least one single plate connected to said containment element.

According to an aspect of the present invention, the containment element may be made of at least one of Invar, Kovar, Alloy 42 or FeNi alloys, Titanium or alloys thereof, Aluminum or alloys thereof, Steel, Brass, Macor. According to an aspect of the present invention, the guides may be made of a ceramic material.

According to an aspect of the present invention, the containment element may comprise a plurality of housing seats defined by internal arms.

The characteristics and advantages of the method and of the probe card according to the invention will be apparent from the description, made hereinafter, of an embodiment thereof, given by way of indicative and non-limiting example, with reference to the enclosed drawings.

### BRIEF DESCRIPTION OF THE DRAWINGS

In the drawings:

FIG. 1 schematically shows a probe card according to the prior art;

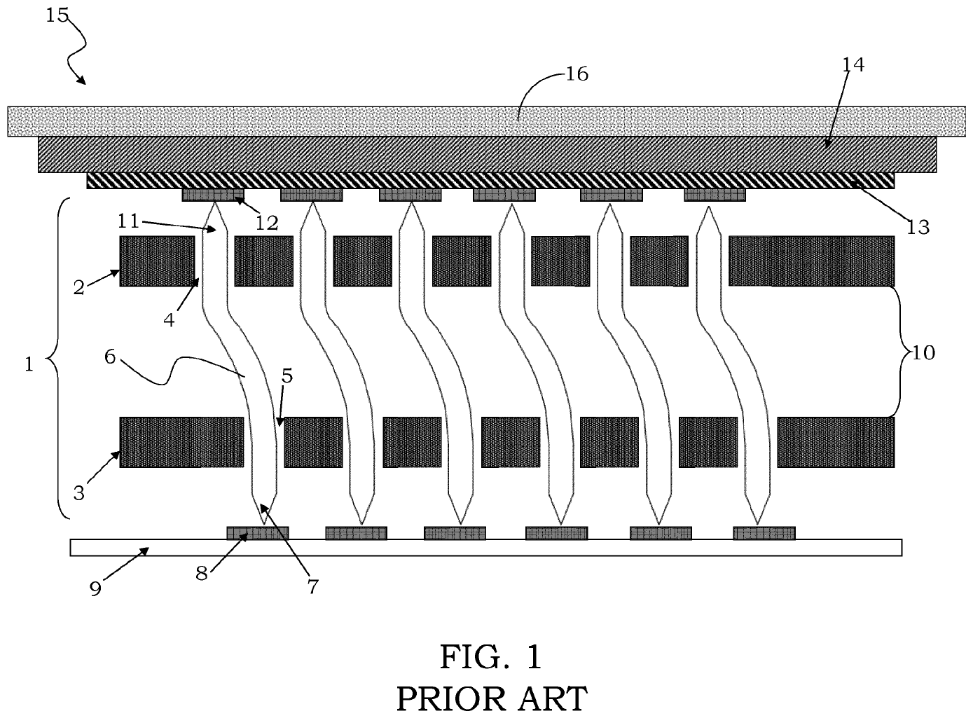

FIG. 2 schematically shows a probe card according to the present invention;

FIG. 3 is a flow chart that shows steps of the method of the present invention;

FIG. 4 shows a schematic top view of a face of a stiffener according to an embodiment of the present invention;

FIGS. 5A and 5B respectively show a perspective view of a portion of a face of an interposer before cutting the same, and a perspective view of a portion of an opposite face of the interposer after cutting the same;

FIG. 6 shows a probe card according to an embodiment of the present invention; and

FIG. 7 shows a schematic top view of a containment element of a probe head of the probe card of FIG. 6.

### DETAILED DESCRIPTION

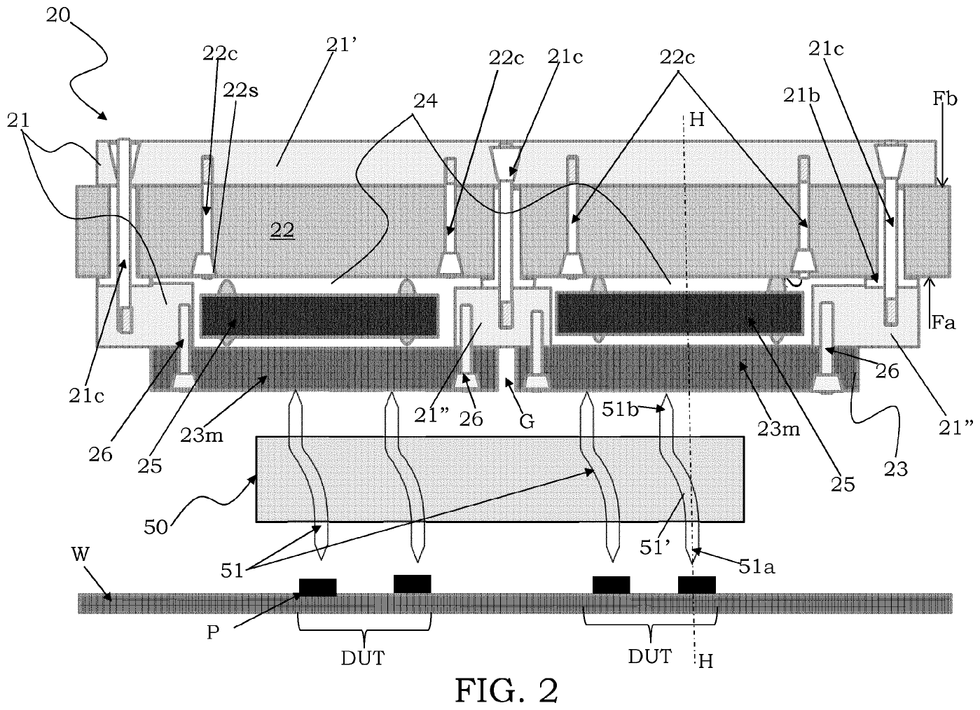

With reference to those figures, and in particular to FIG. 2, a probe card for testing electronic devices that are integrated on a semiconductor wafer according to the present invention is globally and schematically indicated with 20.

It is worth noting that the figures represent schematic views and are not drawn to scale, but instead they are drawn so as to emphasize the important features of the invention. Moreover, in the figures, the different elements are depicted in a schematic manner, and their shape may vary depending on the application desired. It is also noted that, in the figures, the same reference numbers refer to elements that are identical in shape or function. Finally, particular features described in relation to an embodiment illustrated in a figure are also applicable to the other embodiments illustrated in the other figures.

It is also noted that, unless it is expressly indicated, the method steps may also be reversed if necessary.

As it will be illustrated hereinafter, the probe card 20 of the present invention is particularly suitable for testing memory devices, such as for instance DRAMs, thanks to the large size thereof. In fact it is immediately observed that, as a whole, the area under test may also reach 300 mm (in this case the probe cards are referred to as 12-inch size probe cards), so that, as a whole, the probe card 20 of the present invention may also reach dimensions of 520 mm. For instance, in embodiments in which the probe card 20, as a whole, has a circular shape (and thus it comprises circular-shaped guides), its maximum diameter may be of about 520 mm.

Obviously, the above illustrated application is merely indicative and the probe card 20 of the present invention may be used for testing many other electronic devices. For instance, another one of the many applications is in the automotive field.

As illustrated in the embodiment of FIG. 2, the probe card 20 comprises a stiffener 21 including in turn a first stiffener portion 21′ and a second stiffener portion 21″. The stiffener 21 has the purpose of keeping in position the components of the probe card 20 and of solving planarity (flatness) problems.

In particular, in an embodiment of the present invention, the first stiffener portion 21′ and the second stiffener portion 21″ are initially structurally independent from each other, i.e., the stiffener 21 is substantially structured in two separated stiffeners. The first stiffener portion 21′ is also called “upper stiffener” and the second stiffener portion 21″ is also called “lower stiffener”. The first stiffener portion 21′, during the test, is closer to the testing apparatus (not illustrated in the figures), whereas the second stiffener portion 21″, during the test, is closer to the wafer W including the devices under test (herein referred to as DUT).

Furthermore, the probe card 20 comprises an interface board (or support plate) 22 configured to interface said probe card 20 with the testing apparatus. More particularly, the interface board 22 is a printed circuit board (also indicated as PCB).

The interface board 22 comprises at least one lower face Fa which, during the test, faces towards the wafer W including the devices under test DUT, and one upper face Fb opposite the lower face Fa.

As illustrated in FIG. 2, the interface board 22 is arranged between the first stiffener portion 21′ and the second stiffener portion 21″, substantially forming a sandwich configuration.

For instance, the interface board 22 has a thermal expansion coefficient (CTE) of about 16 ppm/° C. (10⁻⁶/° C.). In order to limit the effects of the thermal expansion of the interface board 22 during the test, in an embodiment of the present invention, said interface board 22 is associated with the stiffener 21 in a floating manner.

More particularly, connecting elements with clearance 22c are provided for connecting the interface board 22 to the stiffener 21 (in particular to the first stiffener portion 21′), said connecting elements with clearance 22c (such as for instance suitable screws) being floatingly housed in a plurality of respective seats 22s (such as for instance suitable slotted holes) formed in said interface board 22, so as to make a floating association of the interface board 22 with the stiffener 21.

Moreover, the connection between the first stiffener portion 21′ and the second stiffener portion 21″ is such as to allow the relative movement of the interface board 22 arranged there between, at least in the plane x-y (i.e. in the plane wherein the wafer W lies, and possibly slightly also along the vertical axis z), to avoid fixedly constraining said support plate 22.

As illustrated in FIG. 2, the first stiffener portion 21′ and the second stiffener portion 21″ are fastened (constrained) to each other by means of a plurality of screws 21c. Bushes 21b may further be provided for favoring the above-mentioned floating of the interface board 22.

Obviously, many other connection ways may also be provided, the figures being provided only by way of non-limiting example of the scope of the present invention.

In an embodiment, the first stiffener portion 21′ and the second stiffener portion 21″ are thus rigidly connected to each other, for instance through screws as above illustrated.

In an embodiment of the present invention, the stiffener 21 is made of a material selected from suitable FeNi alloys (for instance Invar, Kovar, Alloy 42 and other), Titanium or alloys thereof, Aluminum or alloys thereof, Steel, Brass, Macor, however without limiting to these materials.

In general, the CTE of the stiffeners is optimized based on the temperature range at which the probe card 20 operates, which can be controlled thanks to the materials used.

In an embodiment of the present invention, the first stiffener portion 21′ and the second stiffener portion 21″ are respectively made of materials having different CTEs, since during the test a temperature gradient occurs and the first stiffener portion 21′ (which is farthest away from the device under test) preferably has a CTE greater than that of the second stiffener portion 21″. The balancing between said stiffener portions is carried out, as mentioned above, according to the testing platform and the operating temperature range. Obviously, it is possible to use for said components a same material (for instance only Kovar), but with a differently controlled CTE so as to compensate for the aforementioned gradients, as well as to also use different materials (for instance selected from the above cited ones, or to choose particular alloys).

Obviously, the examples provided are only indicative and not limiting of the scope of the present invention, which is not limited by the materials used.

The probe card 20 further comprises an interposer 23 connected to the stiffener 21, in particular connected to the second stiffener portion 21″.

As known in the field, the interposer 23 is adapted to perform a spatial transformation of the distances (pitches) between contact pads on opposite faces thereof, and for this reason said component is also called “space transformer”.

Advantageously according to the present invention, the interposer 23, when connected to the second stiffener portion 21″, is in the shape of a monobloc of material. In particular, the interposer 23 is connected to the stiffener 21 as a single component (for instance a single board), in the form of said monobloc.

Once the interposer 23 has been connected to the stiffener 21 (in particular connected to the lower face of the second stiffener portion 21″ facing towards the devices under test DUT), it is cut according to a predetermined pattern, thereby defining a plurality of modules 23m which are independent and separated from each other. In particular, at the end of the cutting, the single modules 23m are separated from each other by suitable gaps or trenches G.

In other words, at the end of the probe card 20 manufacturing, the interposer 23 comprises a plurality of modules 23m separated from each other, said modules 23m being obtained by cutting the monobloc of material that is initially connected to the second stiffener portion 21″.

In this way, at least one single monobloc of material is initially provided, i.e. a single structural element in which there are no elements completely separated from each other and which is cut only further to the initial connection with the stiffener 21.

This greatly simplifies the assembly and setup process of the probe card since it is no longer necessary to align the single modules (which would be instead required if said modules were associated directly with the stiffener when already singularized). The structural independence of the modules ensures a greater control of the thermal expansion of the components during the test, in particular at extreme temperatures, as it will be specified later.

In an alternative embodiment, it is also possible to use more than one monobloc of material (for instance two or three, in any case in a limited number), said monoblocs however being always subsequently divided into many independent modules after the connection to the stiffener.

Still referring to FIG. 2, the probe card 20 further comprises a probe head 50, which includes a plurality of contact elements 51 (for instance contact probes) adapted to electrically connect the interposer 23 with contact pads P of the devices under test DUT integrated in the semiconductor wafer W.

Summing up, the present disclosure substantially relates to a manufacturing method of the above described probe card 20, comprising at least the steps of:
providing the stiffener 21 comprising the first stiffener portion 21′ and the second stiffener portion 21″;
connecting the interposer 23 to the second stiffener portion 21″, said interposer 23 being in the form of a monobloc of material;
cutting the interposer 23 according to a predetermined pattern after connecting it to the second stiffener portion 21″, thereby defining a plurality of modules 23m separated from each other (in this way, after cutting, the interposer 23 is structured and divided into the plurality of independent modules 23m);
providing the interface board 22;
arranging the interface board 22 between the first stiffener portion 21′ and the second stiffener portion 21″;
fastening (constraining) the first stiffener portion 21′ and the second stiffener portion 21″ to each other; and
associating the probe head 50 with the interposer 23, said probe head comprising the plurality of contact elements 51 adapted to electrically connect the interposer 23 with the contact pads P of the device under test DUT.

Obviously, apart from the sequence that provides first the connection of the interposer 23 to the stiffener 21 and then the cutting of said interposer 23, all the other steps do not necessarily follow a certain fixed sequence. For instance, as above illustrated, it is possible to first connect the interposer 23 to stiffener 21 (in particular to the second stiffener portion 21″) and cut said interposer 23, and then to connect the second stiffener portion 21″ to the first stiffener portion 21′, even if other suitable sequences are not excluded.

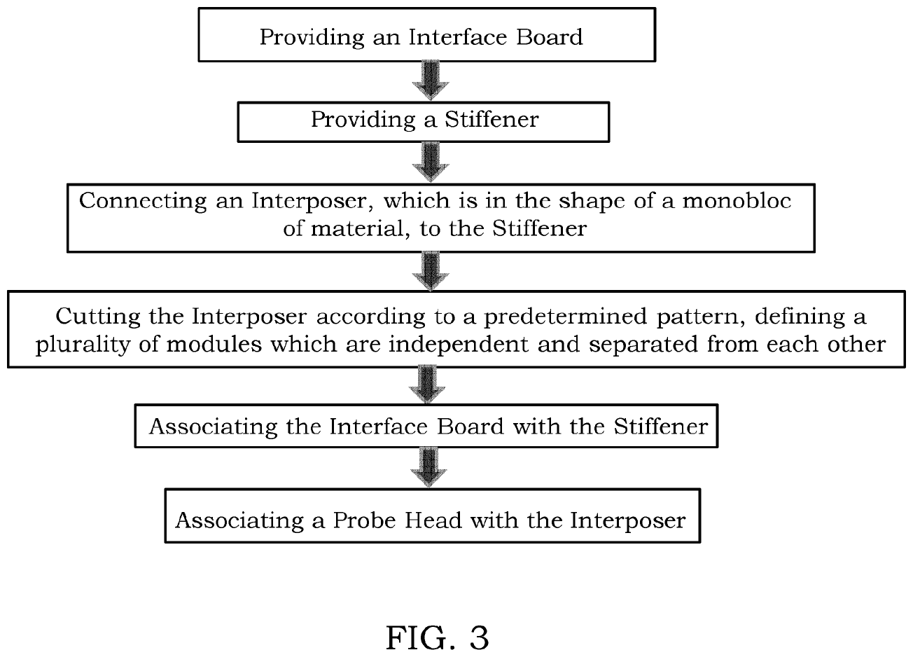

In general, as schematized in FIG. 3, the method of the present disclosure, in its most general form, provides at least the following steps:
providing the interface board 22, which is configured to interface the probe card 20 to a testing apparatus;
providing the stiffener 21;
connecting the interposer 23 to the stiffener 21, said interposer 23 being in the shape of at least one monobloc of material;
cutting the at least one monobloc of the interposer 23 according to a predetermined pattern after connecting it to the stiffener 21, thus defining a plurality of modules 23m which are independent and separated from each other;
associating the interface board 22 with the stiffener 21; and
associating a probe head 50 with the interposer 23, said probe head 50 comprising a plurality di contact elements 51 adapted to electrically connect the interposer 23 with contact pads P of the devices under test DUT.

It is noted that, herein, the term “to associate” means to connect, both directly and indirectly, an element with another, not necessarily in a rigid manner.

Furthermore, in a preferred embodiment of the present invention, the cutting of the interposer 23 is carried out by cutting laser. Alternatively, it is also possible to use water cutting (Water Jet), or a combination of the above techniques. In any case, the cutting of the interposer that determines the total separation between the modules (that is, their relative independence), always occurs after the assembly thereof on the stiffener.

As above mentioned, the interposer 23 is adapted to route the signals carried by the contact elements 51 and to allow a redistribution of the contact pads on the PCB. According to prior art solutions, the space transformers are made of a Multi-Layer Ceramic (MLC). Advantageously according to embodiments of the present invention, the interposer 23 is instead made of a Multi-Layer Organic material (MLO). The use of an MLO ensures a greater flexibility with respect to a ceramic material, as well as a greater ease of processing (for instance making laser cutting easier, with consequent savings in production costs).

Still with reference to FIG. 2, the contact elements 51 comprise a body 51′ which extends along a longitudinal axis H-H between a first end 51a and a second and opposite end 51b. The first end 51a is adapted to contact the contact pads P of the devices under test DUT, whereas the second end 51b is adapted to contact the interposer 23 in a non-fixed manner. In this way, the contact elements 51 are not fixedly fastened and constrained to the interposer 23.

Suitably, in a preferred embodiment, the contact elements 51 are vertical contact probes, so that it is possible to take advantage of all the advantages of this vertical technology.

According to an embodiment of the present invention, the second stiffener portion 21″ comprises a plurality of housing seats 24, and at each of said housing seats 24 a correspondent module of the plurality of modules 23m of the interposer 23 is arranged. The housing seats 24 may be through-holes made in the second stiffener portion 21″ and are in a number identical to that of the modules 23m of the interposer 23, which are arranged at respective housing seats 24.

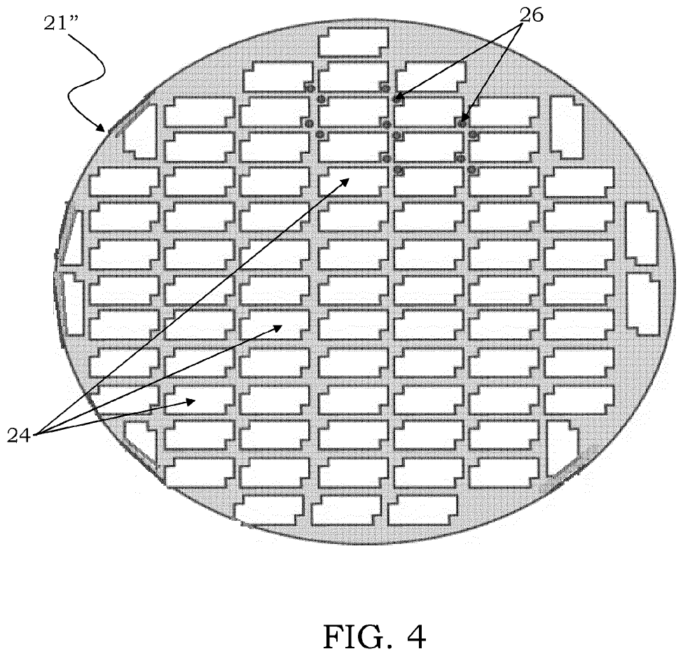

FIG. 4 shows a non-limiting example of the second stiffener portion 21″ seen from above, wherein the various housing seats 24 are visible. Though in FIG. 4 the housing seats 24 have all the same shape (apart from the peripheral housing seats which have different shapes to fit the edge of the interposer), they may also have different shapes, as well as the modules 23m may have shapes different from each other.

In other words, in some embodiments, the present disclosure provides preliminary defining in the second stiffener portion 21″ the plurality of housing seats 24, so that corresponding modules of the plurality of modules 23m of the interposer 23 will be cut at said housing seats 24, each module being cut at the respective housing seat.

The design of the stiffener 21, for instance of the second portion 21″ thereof, may thus be complex. In an embodiment of the present invention, the stiffener 21 is shaped by water cutting or wire EDM or, less preferably, chip removal, although other processes are possible and not excluded.

In an embodiment of the present invention, the probe card 20 comprises a plurality of electrical connection elements 25 housed in the housing seats 24 and configured for electrically connecting the interposer 23 and the interface board 22 to each other. In this way, during the manufacturing of the probe card 20, according to some embodiments, the electrical connection elements 25 are inserted into the respective housing seats 24 before connecting the interposer 23 to the second stiffener portion 21″.

By way of example, the electrical connection elements 25 may be in the form of conductive elastomers, pogo pins or conductive clips, or the like.

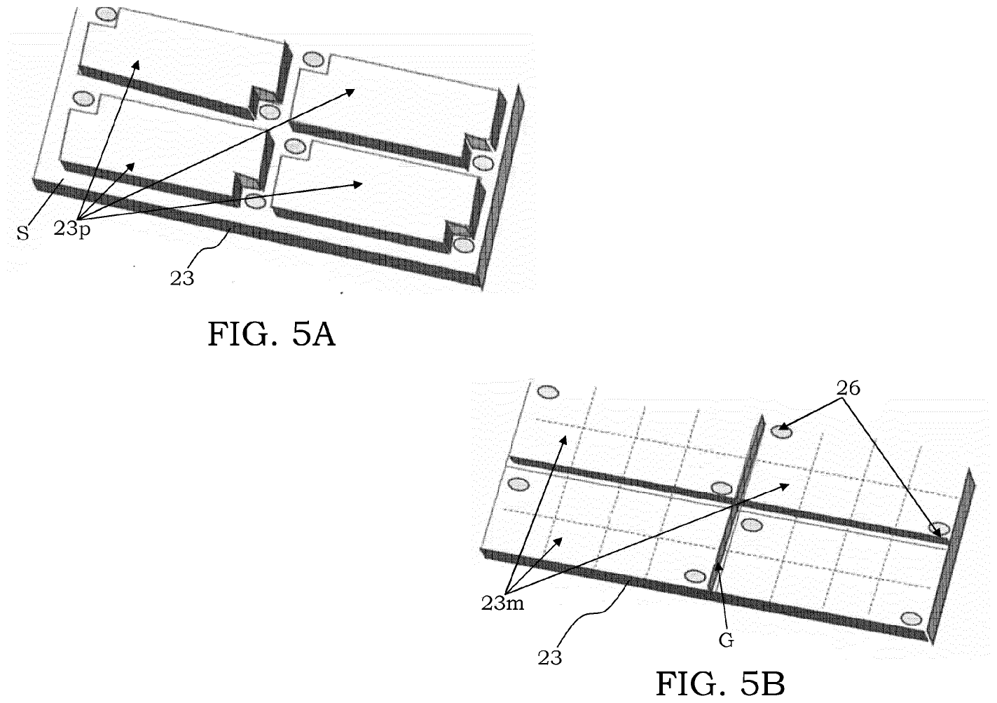

Furthermore, according to an advantageous embodiment of the present invention illustrated in FIGS. 5A and 5B, each module 23m comprises a projection 23p inserted in a respective housing seat of the plurality of housing seats 24 of the second stiffener portion 21″. More particularly, said projections 23p are formed by shaping the monobloc of material of the interposer 23 (for instance by milling said monobloc of material) before connecting it to the second stiffener portion 21″ and thus before cutting said monobloc of material. By way of example, the projections 23p may protrude from the body of the monobloc of material by a value for instance variable between 0.5 mm and 4 mm, preferably 2 mm, said value ensuring a good strength in the fixing area.

In other words, in this embodiment, each module 23m comprises the projection 23p housed in the respective housing seat 24, as well as a lowered portion (i.e. shoulder S) abutting onto the lower face of the second stiffener portion 21″.

According to embodiments of the present disclosure, each module of the plurality of modules 23m is constrained to the second stiffener portion 21″ through screws 26, preferably through two screws 26. For instance, as illustrated in FIGS. 5A and 5B, screw 26 at two opposite corners of each module 23m may be provided.

Obviously, it is possible to use a different number of screws, as well as it is possible to adopt different attachment methods of the interposer 23 to the second stiffener portion 21″. For instance, in an alternative embodiment, the interposer 23 may be glued to the second stiffener portion 21″.

In any case, regardless of the connection mode, the interposer 23 is always fastened (constrained) to the stiffener 21 (e.g., to the second stiffener portion 21″) as a monobloc of material prior to being cut. The complete separation into modules therefore always occurs after fixing said monobloc to the stiffener 21.

The interposer 23 may comprise a high number of modules 23m, for instance a number of modules which varies from 50 to 150. Each module is configured to test a plurality of devices, for instance a number of devices from 1 to 30. It is thus clear that, with a single testing operation, the probe card 20 of the present invention, thanks to its large size and to the large number of modules 23m associated therewith, is able to carry out the testing of a high number of devices, being at the same time easy to assemble and ensuring an excellent control of the thermal expansion of its components.

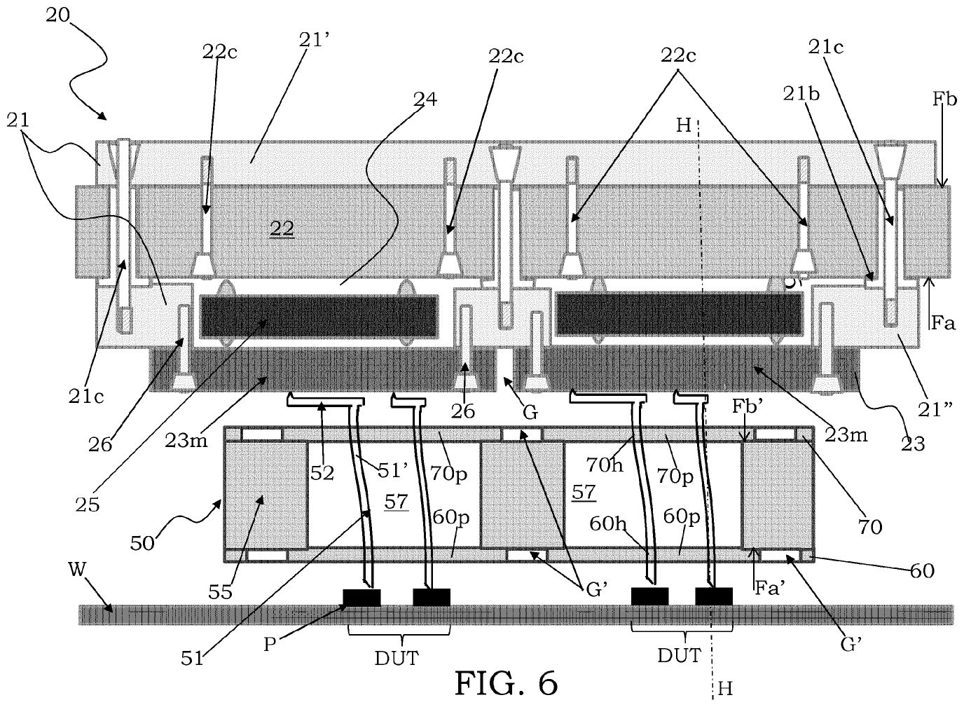

Referring now to the embodiment of FIG. 6, the probe head 50 associated with the probe card 20 comprises a containment element or housing 55 configured to house (at least partially) the contact elements 51.

The containment element 55 is preferably made of a material selected from suitable FeNi alloys (for instance Invar, Kovar, Alloy 42 and others), Titanium or alloys thereof, Aluminum or alloys thereof, Steel, Brass, Macor, however without limiting to these materials. In general, the CTE of the containment element 55 is selected so as to compensate for the variations of the wafer W made of silicon, considering the temperature gradients that arise inside the probe card and in particular the probe head. In general, the silicon CTE is less than 2 ppm/° C. (10⁻⁶/° C.) and the CTE progressively increases in the probe card away from the wafer W. Indicatively, the optimal CTE of the containment element 55 is between 3 and 6 ppm/° C. (10⁻⁶/° C.).

The probe head 50 further comprises a lower guide 60 arranged at a lower face Fa′ of the containment element 55 (i.e. the face that faces towards the devices under test DUT) and an upper guide 70 arranged at an opposite upper face Fb′ of said containment element 55.

In an embodiment of the present invention, both the lower guide 60 and the upper guide 70 are made of a ceramic material. In general, said guides have a CTE comprised between 1.8 and 5 ppm/° C. (10⁻⁶/° C.).

The containment element 55 is thus interposed between the lower guide and the upper guide 70 and is adapted to support said guides, providing a rigid support structure of the probe head 50 as a whole.

The probe head 50 is a vertical probe head, wherein the contact elements 51 are movable within lower guide holes 60h and upper guide holes 70h made in the respective guides 60 and 70.

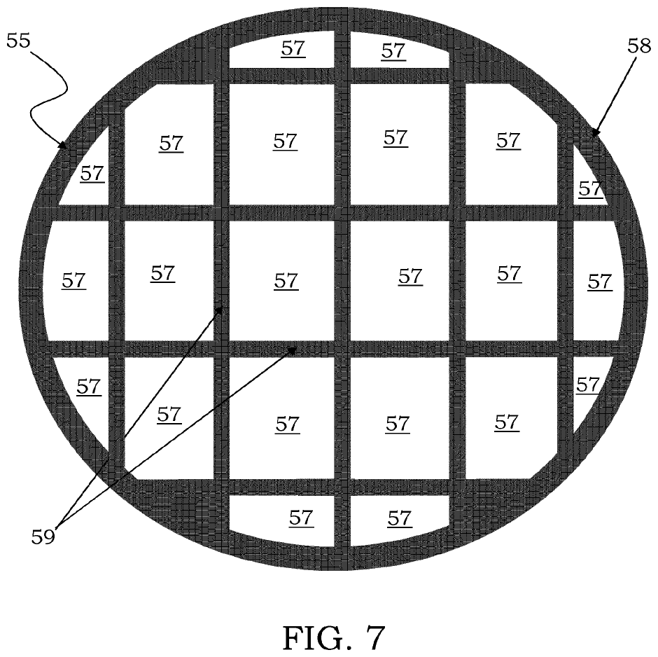

In an embodiment of the present invention, the containment element 55 is in the shape of a block comprising a plurality of housing seats 57 therein made, the contact elements 51 being housed in groups in said housing seats 57. In other words, the containment element 55 does not only comprise a single internal empty space defined by its outer perimeter 58 but, as illustrated in FIG. 7, it comprises a series of internal partitions (i.e. the above housing seats 57) defined by internal walls or arms 59, which provide support to the guides which then are placed thereonto. It is substantially a metal mesh structure (metallic hive), wherein the arms 59 define said mesh for supporting the guides.

Obviously, the structure represented in FIG. 7 is just indicative and does not limit the scope of the present invention. For instance, though said figure represents housing seats 57 of substantially the same shape (apart from the peripheral housing seats), it is also possible to adopt a configuration in which the internal partition of the containment element is less regular. Furthermore, it is not necessary for the housing to be circular-shaped, and any suitable shape may be used. For instance, the shape may also be polygonal (octagonal, hexadecagonal, etc.) or even square or rectangular.

Still referring to FIG. 6, according to a further advantageous embodiment of the present invention, at least the lower guide 60 (preferably both guides 60 and 70) comprises a plurality of guide portions separated from each other by gaps G′, said guide portions 60p being obtained by cutting a single plate which was initially connected to the containment element 55. As previously mentioned, it is preferable that also the upper guide 70 is divided into a plurality of guide portions 70p separated from each other by gaps G′. These various guide portions (which are independent and separated from each other) are mechanically supported by the containment element 55 which, as previously seen, acts as a support structure thanks to the presence of the arms 59 which are configured to support said single guide portions 60p and 70p.

In general, there is no relationship between the partition of the guides and the partition of the interposer, even if, in particular embodiments, the possibility of adopting a same pattern for interposer and guides is not excluded.

In other words, the probe head 50 is manufactured at least through the following steps:
providing the containment element 55 for at least partially housing the contact elements 51;
arranging the lower guide 60 at the lower face Fa′ of the containment element 55;
arranging the upper guide 70 at the upper face Fb′ of the containment element 55, so that the containment element 55 is interposed between the lower guide 60 and the upper guide 70.

Both guides 60 and 70 are initially in the shape of a single plate connected to the containment element 55, so that the method further comprises the step of:
cutting at least the lower guide 60 (preferably both guides 60 and 70) thereby defining a plurality of guide portions 60p which are independent and separated from each other. As seen for the interposer 23, the guides are preferably cut by laser cutting. As previously mentioned for the interposer 23, it is also possible to use more than one plate (for instance two or three, in any case in a limited number), said plates being anyway always divided into many independent guide portions after their connection to the containment element 55.

Before cutting the guides, the guides holes 60h and 70h are formed by drilling the plates, for instance by laser cutting, and after the cutting, the contact elements 51 (or at least portions thereof) are finally inserted into said guide holes. A sequence, less preferred, in which the guide holes are formed on the guide portions after the cutting is however also possible.

In an embodiment, the lower guide 60 and the upper guide 70 are glued to the containment element 55 before cutting said guides, although other connection methods are possible.

The probe head 50 is then fastened to the rest of the probe card 20, in particular to the second stiffener portion 21″, for instance through screws.

Advantageously, similarly to what has been seen for the interposer 23, the presence of the various guide portions 60p and 70p separated from each other allows an effective control of the thermal shifts that occur during the tests, in particular during the tests at extreme temperatures. The aforementioned processing sequence, which first provides the connection of the guides 60 and 70 in the form of a single plate to the containment element 55 and afterwards the cutting thereof into separated modules (guide portions), is very advantageous since it eliminates the need to place in various positions and align the guide portions to each other, which would be extremely complicated and long, resulting in savings in production times and costs.

Thanks to this configuration, the thermal expansion of the probe head 50 is mainly linked to the CTE of the containment element 55, which may be controlled in a simple manner (by selecting and calibrating one of the aforementioned materials) so as to compensate the variations of the wafer W, the separation between the guide portions allowing to release said guide portions from the variations of the housing 55.

Finally, in an embodiment of the present invention, the second end 51b of the contact elements 51 is structured so as to comprise an arm 52 laterally projecting from the probe body 51′ and configured to perform the contact with the interposer 23, said arm 52 being adapted to decentralize the contact point between the contact element 51 and said interposer 23 with reference to the longitudinal axis H-H of the probes 51.

In other words, in this embodiment, the contact elements 51 of the probe head 50 have contact heads provided with arms protruding from the probe body and adapted to contact the interposer, said arms extending in length differently from probe to probe so as to allow an effective spatial redistribution of the contact pads of the probe card with respect to contact pads of the devices under test DUT, in particular relaxing the pitch constraints of said devices under test. The lengths or relative longitudinal extensions of the arms may be selected based on the needs in order to obtain the best redistribution of the contact pads, and thus the best routing of the signals, and configurations are also provided in which not all of the probes include protruding arms. For the sake of clarity, it is noted that the length of the arms 52 is measured along their longitudinal development direction (for instance orthogonal to the axis H-H of the probes).

Suitably, as above illustrated, the probe card of the present disclosure allows the use of a vertical probe head with vertical contact probes, thus exploiting all the potential of the vertical technology as described above.

In an embodiment, in order to ensure the correct holding of the contact elements 51, their portion housed in the upper guide holes 70h is provided with a suitable holding system (not illustrated in the figures, for instance a spring or clip structure, or a structure in which an appropriate surface corrugation/irregularity allows a better retention in the guide holes). This configuration adopted for the contact elements 51 allows not to perform a shift between the lower and upper guides during the assembly, said shift being done for deforming the probe body to favor deflection and hold the probes, which instead are held as above illustrated. Only a small (almost imperceptible) pre-deformation of the probe body 51′ is sufficient to ensure that, during the test, all probes bend in a same direction. The fact that the guides (or rather their corresponding guide holes) are not shifted with respect to each other allows dividing into a plurality of guide portions 70p even the upper guide and not only the lower guide 60, with even better thermal shift control. In other words, the above holding system allows not to perform the shift of the guides for holding the probes, so as to easily cut also the upper guide 70, thus obtaining a greater flexibility in the control of the thermal shifts.

In conclusion, the present invention provides a probe card manufactured through a methodology whereby the interposer is initially constrained to a stiffener in the form of a monobloc of material and subsequently cut into a plurality of modules which are independent and separate from each other. In this way, the interposer is initially associated with the probe card as a single block of material, without the need to align the single modules, which then allow an improved control of the thermal expansion of the probe card during the test.

Advantageously according to the present invention, it is thus possible to control in an extremely simple manner the thermal expansion of the components of the probe card during tests at extreme temperatures, significantly reducing, if not completely eliminating, the harmful effects of said thermal expansion. The probe card of the present disclosure is thus able to withstand and bear great temperature variations (for instance from −40° C. to +125° C.) without undergoing bending and arching of its components.

More particularly, thanks to the presence of the various modules of the interposer separated from each other, said interposer is not linked to the thermal expansion coefficient of the stiffener (i.e., it is not affected by the expansion of the latter), so that the expansion of such stiffener does not cause mechanical stress of the interposer thanks to the free spaces between one module and the other, which allow a relative movement thereof.

The thermal expansion of the overall probe card is thus mainly due to the contribution of the upper stiffener and of the lower stiffener, whose thermal expansion coefficient may be calibrated in such a way that these components can expand without creating bending, thus ensuring the probe card planarity over the entire range of test temperatures (which, as previously observed, may vary between extreme values). In other words, the relative independence of the modules of the interposer (as well as the floating association of the PCB with the stiffeners) ensures that the global thermal expansion coefficient of the probe card is only substantially managed by the stiffeners, so that it is easier to compensate for the temperature gradients and the different expansions within the probe card.

Suitably according to the present invention, this configuration is obtained in an extremely simple manner, initially constraining the interposer to the stiffener (in particular to the second stiffener portion closest to the wafer) and completely separating the various modules only afterwards, i.e. only after the connection. Advantageously, the adopted solution allows to avoid aligning the various modules to each other, since they are already perfectly aligned once the interposer is cut (which is initially in the shape of a single piece of material), greatly simplifying the manufacture and use of the probe card of the present invention. All this involves a considerable saving in production times and costs, at the same time obtaining a much more reliable solution, since there are no relative alignment errors between the various components.

Furthermore, the use of a MLO for the space transformer makes the above process easier and cheaper.

This is particularly advantageous in case of large probe heads, such as for instance those used in the test of memory devices such as DRAMs, for which the relative alignment of the various components is even more delicate because of the large size, and for which the thermal expansion of the various components is even more critical.

The combined use of said probe card with a probe head also having the guides divided into various separate and independent portions allows for an even finer and more effective control of the thermal expansion during tests at extreme temperatures. In this case, it is in fact possible to control the CTE both at the interposer level and at the probe head level, increasing the degree of thermal control of the probe card as a whole. In other words, by separating from each other the various guide portions, it is possible to control the thermal expansion of the probe head part by only controlling the thermal expansion of the housing (for which it is possible to have an easy control), and thus obtaining an extra degree of freedom in the thermal control of the components of the probe card: it is therefore easier to manage the tolerance to thermal shifts, which are spread over multiple interfaces.

Obviously, a person skilled in the art, in order to meet contingent and specific requirements, may make to the method and to the probe card above described numerous modifications and variations, all included in the scope of protection of the invention as defined by the following claims.

1. A method for manufacturing a probe card for the functionality testing of devices under test, the method comprising the steps of:
providing an interface board configured to interface the probe card to a testing apparatus;
providing a stiffener;
connecting an interposer to the stiffener, the interposer being in the shape of a monobloc of material;
cutting the monobloc of the interposer according to a predetermined pattern after connecting the monobloc it to the stiffener, thereby defining, starting from said monobloc, a plurality of modules which are independent and separated from each other;
associating the interface board with the stiffener; and
associating a probe head with the interposer, the probe head comprising a plurality of contact elements adapted to electrically connect the interposer to contact pads of the devices under test.

2. The method according to claim 1, wherein the stiffener comprises a first stiffener portion and a second stiffener portion, the method comprising the step of:
arranging the interface board between the first stiffener portion and the second stiffener portion,
wherein the interposer is connected to the second stiffener portion.

3. The method according to claim 1, wherein the cutting of the interposer is performed by laser cutting or water cutting or a combination thereof.

4. The method according to claim 1, wherein the monobloc of material of the interposer is made of a multilayer organic material.

5. The method according to claim 1, wherein the interposer is fastened to the stiffener by means of screws or glue.

6. The method according to claim 1, further comprising the step of associating the interface board with the stiffener by means of connecting elements with clearance the connecting elements with clearance being floatingly housed in a plurality of respective seats made in the interface board, so as to make a floating association of the interface board with the stiffener.

7. The method according to claim 2, further comprising the preliminary step of defining a plurality of housing seats in the second stiffener portion, the housing seats being in a number identical to that of the modules of the plurality of modules of the interposer, which are arranged at respective housing seats.

8. The method according to claim 7, further comprising the preliminary step of shaping the monobloc of material of the interposer to form a plurality of projections therein, the projections being housed in corresponding housing seats of the second stiffener portion before cutting said monobloc of material.

9. The method according to claim 7, further comprising the step of inserting a plurality of electrical connection elements into the housing seats, the electrical connection elements being configured to electrically connect each module of the plurality of modules of the interposer with the interface board.

10. The method according to claim 1, further comprising the step of selecting the stiffener material among Invar, Kovar, Alloy 42 or FeNi alloys, Titanium or alloys thereof, Aluminum or alloys thereof, Steel, Brass, Macor.

11. The method according to claim 1, wherein the probe head is manufactured through the following steps:
providing a containment element configured to house at least partially the contact elements;
arranging a lower guide at a lower face of the containment element, the lower face facing towards the devices under test during the test;
arranging an upper guide at an upper face of the containment element, the upper face being opposite the lower faces,
wherein the containment element is interposed between the lower guide and the upper guide, and wherein the guides are in the shape of at least one a single plate connected to the containment element,
the method further comprising the step of:
cutting at least one of the lower guide or the upper guide thereby defining a plurality of guide portions which are independent and separated from each other.

12. The method according to claim 11, further comprising the preliminary step of gluing the lower guide and the upper guide to the containment element, and the step of forming in the guides respective guide holes for housing the contact elements, said step being performed prior to the gluing and cutting step.

13. A probe card for the functionality testing of devices under test, comprising:
a stiffener;
an interface board associated with the stiffener and configured to interface the probe card to a testing apparatus; and
an interposer connected to the stiffener, said, the interposer comprising a plurality of modules which are independent and separated from each other,
wherein said modules of the interposer are obtained by cutting at least one a monobloc of material which is initially connected to the stiffener,
the probe card further comprising a probe head comprising a plurality of contact elements which are adapted to electrically connect the interposer to contact pads of the devices under test.

14. The probe card according to claim 13, wherein the stiffener comprises a first stiffener portion and a second stiffener portion, the interface board being arranged between the first stiffener portion and the second stiffener portion, and wherein the interposer is connected to the second stiffener portion.

15. The probe card according to claim 13, wherein the interposer is made of a multilayer organic material.

16. The probe card according to claim 13, wherein the contact elements comprise a body which extends along a longitudinal axis between a first end and a second and opposite end, the first end O-being adapted to contact the contact pads of the devices under test, the second end being adapted to contact the interposer in a non-fixed manner.

17. The probe card claim 13, wherein the interface board is a printed circuit board.

18. The probe card claim 13, wherein the interposer comprises a number of modules ranging from 50 to 150.

19. The probe card claim 13, wherein the stiffener is made of at least one of Invar, Kovar, Alloy 42 or FeNi alloys, Titanium or alloys thereof, Aluminum or alloys thereof, Steel, Brass, Macor.

20. The probe card claim 13, further comprising connecting elements with clearance apt to connect the interface board to the stiffener, said, the connecting elements with clearance being floatingly housed in a plurality of respective seats made in saw the interface board, said, the connecting elements with clearance being configured to associate the interface board with the stiffener in a floating manner.

21. The probe card according to claim 14, wherein each module of the plurality of modules is fastened to the second stiffener portion by means of at least two screws.

22. The probe card according to claim 14, wherein the second stiffener portion comprises a plurality of housing seats, and wherein at each of the housing seats a corresponding module of the plurality of modules of the interposer is housed.

23. The probe card according to claim 22, further comprising a plurality of electrical connection elements which are housed in the housing seats and are configured to electrically connect the interposer and the interface board to each other.

24. The probe card according to claim 22, wherein each module further comprises a projection inserted in a respective housing seat of the plurality of housing seats of the second stiffener portion.

25. The probe card claim 13, wherein the probe head comprises:
a containment element configured to house at least partially the contact elements;
a lower guide arranged at a lower face of the containment element, said, the lower face facing towards the devices under test during the test; and
an upper guide arranged at an upper face of the containment element, the upper face being opposite the lower face,
wherein the containment element is interposed between the lower guide and the upper guide, and
wherein at least one of the guides is divided into a plurality of guide portions separated from each other, the guide portions being obtained by cutting at least one single plate connected to the containment element.

26. The probe card according to claim 25, wherein the containment element is made of at least one of Invar, Kovar, Alloy 42 or FeNi alloys, Titanium or alloys thereof, Aluminum or alloys thereof, Steel, Brass, Macor, and/or wherein the guides are made of a ceramic material.

27. The probe card according to claim 25, wherein the containment element comprises a plurality of housing seats defined by internal arms.
